(19) United States
(12) Patent Application Publication
(10) Pub. No.: US 2006/0124617 A1
(43) Pub. Date: Jun. 15, 2006

(54) High-power solid-state laser dicing apparatus for a gallium nitride wafer and dicing method thereof

(76) Inventor: Chih-Ming Hsu, Lu-Zhu (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/211,443

(22) Filed: Aug. 26, 2005

(30) Foreign Application Priority Data
Dec. 14, 2004 (TW) 93138748

(51) Int. Cl. B23K 26/38; B23K 26/03; H01L 21/301

(52) U.S. Cl. 219/121.67; 219/121.75; 438/463; 219/121.83

(57) ABSTRACT

The present invention discloses a high-power solid-state laser dicing apparatus for a gallium nitride wafer and a dicing method thereof, wherein a gallium nitride wafer is disposed on a working table; the gallium nitride wafer has multiple chips or dice with a scribed line drawn between every two chips or dice; a light-guide device is used to direct a high-power solid-state laser to one of the scribed lines on the gallium nitride wafer; a control device is used to position the working table and the high-power solid-state laser so that the high-power solid-state laser can be precisely aimed at one of the scribed lines on the gallium nitride; and the high-power solid-state laser is then used to cut the gallium nitride wafer in order to separate the gallium nitride wafer into multiple discrete chips or dice. The present invention can save the manpower, cost and time of cutting a gallium nitride wafer, and can precisely cut a gallium nitride wafer without injuring the surface of the gallium nitride wafer.

### BACKGROUND OF THE INVENTION

1. Field of the Invention

The present invention relates to a dicing apparatus for a gallium nitride wafer and a dicing method thereof, particularly to a high-power solid-state laser dicing apparatus for a gallium nitride wafer and a dicing method thereof.

2. Description of the Related Art

Gallium nitride—the most advanced semiconductor material—is a group III-V compound semiconductor and has the characteristics of wide energy band gap, high internal and external quantum efficiency, high luminous efficiency, high thermal conductivity, high heat resistance, high radiation resistance, high chemical resistance, high hardness and high strength.

Currently, a gallium nitride wafer is usually cut with a diamond blade or a low-power solid-state laser. However, the laser power reaching the surface of the gallium nitride wafer is lower than 0.5 w, and the cutting speed thereof is so slow that it is less than 40 mm/sec; thus, much manpower, cost and time will be consumed therein. Further, the conventional technology cannot process some gallium nitride wafers, such as a wafer plated with a metallic layer on its back, a wafer having rough surface, an opaque gallium nitride wafer or a gallium nitride wafer having a thickness larger than 150 μm.

Accordingly, the present invention proposes a high-power solid-state laser dicing apparatus for a gallium nitride wafer and a dicing method thereof to overcome the abovementioned problems.

### SUMMARY OF THE INVENTION

The primary objective of the present invention is to provide a high-power solid-state laser dicing apparatus for a gallium nitride wafer and a dicing method thereof, wherein a high-power solid-state laser is used to cut a gallium nitride wafer; the pulse of the laser energy is directed to the surface of the gallium nitride wafer with the laser power reaching its surface ranging from 0.6 to 1.8 w; the high-power solid-state laser with the parameters of a specific wavelength, frequency, energy density and beam diameter will have sufficient energy to enable its pulse to impact and ablate the scribed lines on the gallium nitride wafer so that a gallium nitride wafer can be perfectly diced and an opaque gallium nitride wafer can also be cut.

Another objective of the present invention is to provide a high-power solid-state laser dicing apparatus for a gallium nitride wafer and a dicing method thereof, wherein a high-power solid-state laser is used to rapidly cut a gallium nitride wafer so that the manpower, cost and time can be saved.

Further objective of the present invention is to provide a high-power solid-state laser dicing apparatus for a gallium nitride wafer and a dicing method thereof, wherein a high-power solid-state laser is used to precisely cut a gallium nitride wafer so that the surface injury of the gallium nitride wafer can be avoided.

To achieve the abovementioned objectives, the present invention proposes a high-power solid-state laser dicing apparatus for a gallium nitride wafer, which comprises: a working table, having a vacuum device to fix a gallium nitride wafer, which has multiple chips or dice with a scribed line drawn between every two chips or dice; a high-power solid-state laser, having a power ranging from 0.6 to 1.8 w, and used to cut the gallium nitride wafer; a light-guide device, directing the high-power solid-state laser to the gallium nitride wafer; and a control device, positioning the working table and the high-power solid-state laser so that the high-power solid-state laser can be precisely aimed at one of the scribed lines on the gallium nitride wafer.

The present invention also proposes a high-power solid-state laser dicing method for a gallium nitride wafer, which comprises the following steps: firstly, providing a gallium nitride wafer having multiple chips or dice with a scribed line drawn between every two chips or dice; next, disposing the gallium nitride wafer on a working table; utilizing a control device to position the working table and a high-power solid-state laser so that the high-power solid-state laser can be precisely aimed at one of the scribed lines on the gallium nitride wafer; inputting the length of the scribed line to be cut and the spacing between the scribed line to be cut and another scribed line to be cut next; and lastly, sequentially cutting the scribed lines to separate the gallium nitride wafer into discrete chips or dice.

To enable the objectives, technical contents, characteristics and accomplishments of the present invention to be more easily understood, the embodiments of the present invention are to be described below in detail in cooperation with the attached drawings.

### DESCRIPTION OF THE DRAWINGS

FIG. 1 is a block diagram schematically showing the high-power solid-state laser dicing apparatus for a gallium nitride wafer according to the present invention.

FIG. 2 is a flowchart of the high-power solid-state laser dicing method for a gallium nitride wafer according to the present invention.

FIG. 3 is a diagram schematically showing a scribed line and a cut channel on a gallium nitride wafer in the present invention.

### DETAILED DESCRIPTION OF THE INVENTION

To reduce the expense in the manpower, cost, and time resulting from that the conventional technology uses a diamond blade or a low-power solid-state laser to cut a gallium nitride wafer, the present invention proposes a high-power solid-state laser dicing apparatus for a gallium nitride wafer and a dicing method thereof to overcome those problems.

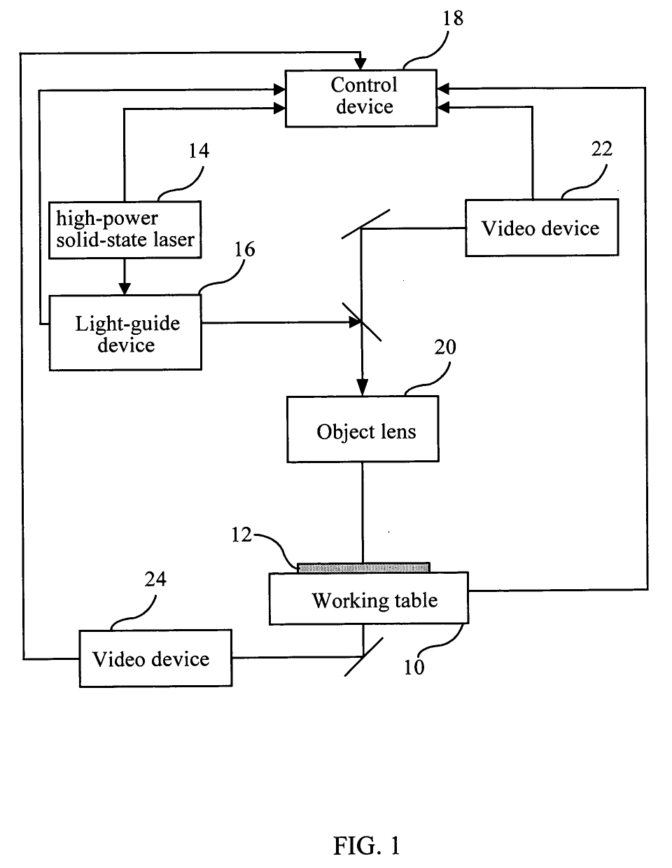

Referring to FIG. 1, the high-power solid-state laser dicing apparatus for a gallium nitride wafer according to the present invention comprises: a working table 10, having a vacuum device (not shown in the drawing) to fix a gallium nitride wafer 12 under a vacuum environment, wherein the gallium nitride wafer 12 may be previously stuck onto a holding film, and the gallium nitride wafer 12 having a thickness from 50 to 500 μm, and then, the gallium nitride wafer together with the holding film is disposed on the working table 10 (as the gallium nitride wafer 12 to be cut must be thinned by grinding beforehand, the gallium nitride wafer 12 may be warped, which may incur the focusing problem of the high-power solid-state laser; therefore, a holding film is used to flatten the gallium nitride wafer 12), and wherein the gallium nitride wafer 12 has multiple chips or dice with a scribed line drawn between every two chips or dice; a high-power solid-state laser 14, used to cut the gallium nitride wafer 12; a light-guide device 16, directing the high-power solid-state laser 14 to the gallium nitride wafer 12; and a control device 18 (such as a computer), controlling the abovementioned devices, including positioning the working table 10 and the high-power solid-state laser 14, i.e. adjust their X and Y coordinates, so that the high-power solid-state laser 14 can be precisely aimed at one scribed line on the gallium nitride wafer 12, which is to be cut.

The high-power solid-state laser dicing apparatus for a gallium nitride wafer according to the present invention may further comprises an object lens 20 that is coupled to the working table 10 and the light-guide device 16 and has a focal-length-adjust element to adjust the focal length by which the high-power solid-state laser 14 is to be precisely aimed at one of the scribed lines on the gallium nitride wafer 12, i.e. to adjust its Z coordinates. The apparatus according to the present invention may further comprises two video devices 22, 24, which are controlled by the control device 18 and used to observe whether the high-power solid-state laser 14 has been precisely aimed at one of the scribed lines when the high-power solid state laser 14 is being positioned to be aimed at the scribed line.

In the present invention, the thickness of the gallium nitride wafer ranges from 50 to 500 μm, and the high-power solid-state laser, which is used to cut the gallium nitride wafer, has the following parameters: a wavelength ranging from 200 to 570 nm, a frequency ranging from 51 to 80 KHz, a pulse duration ranging from 10 to 40 nanosecond, a laser beam diameter ranging 16 to 30 μm, an energy density ranging from 120 to 250 J/cm², and most important of all, a power ranging from 0.6 to 1.8 w. The high-power solid-state laser with the parameters of a specific wavelength, frequency, energy density and beam diameter within the abovementioned ranges will have sufficient energy to enable its pulse to impact and ablate the scribed lines on the gallium nitride wafer in order to rapidly dice the gallium nitride wafer.

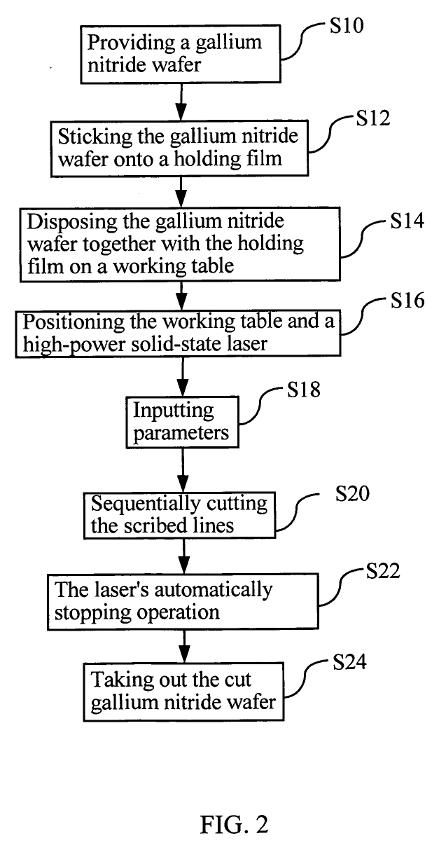

Based on the abovementioned high-power solid-state laser dicing apparatus for a gallium nitride wafer, the present further proposes a high-power solid-state laser dicing method for a gallium nitride wafer. Referring FIG. 2, the high-power solid-state laser dicing method for a gallium nitride wafer according to the present invention comprises the following steps: firstly, providing a gallium nitride wafer, which has multiple chips or dice with a scribed line drawn between every two chips or dice (S10); next, sticking the gallium nitride wafer onto a holding film for flattening the gallium nitride wafer (S12); next, disposing the gallium nitride wafer together with the holding film on a working table, which has a vacuum device to fix the gallium nitride wafer (S14); positioning the working table and a high-power solid-state laser, and utilizing a light-guide device to direct the high-power solid-state laser to the gallium nitride wafer, and utilizing a control device to adjust the X and Y coordinates of the working table and the high-power solid-state laser, and utilizing an object lens having a focal-length-adjust element to adjust the focal length by which the high-power solid-state laser is to be aimed at the scribed line to be cut (S16); next, inputting into the control device the length of the scribed line to be cut and the spacing between the scribed line to be cut and another scribed lined to be cut next (S 18); next, the high-power solid-state laser's sequentially cutting the scribed lines (S20); next, after finishing cutting, the high-power solid-state laser's automatically stopping operation (S22); and lastly, taking out the gallium nitride wafer that has been cut well (S24).

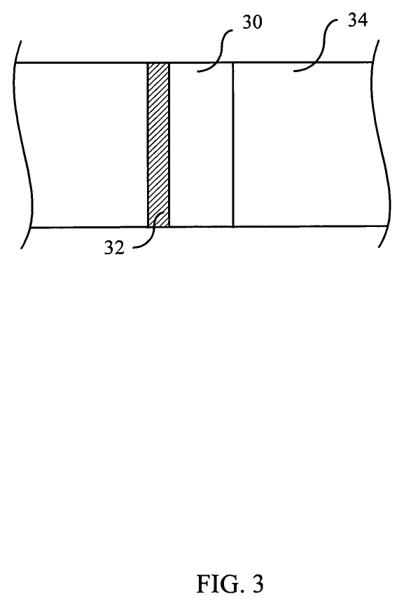

Referring to FIG. 3, as the beam diameter of the high-power solid-state laser used in the present invention is pretty small-ranging from only 16 to 30 μm, the cut channel 32 formed by the high-power solid-state laser will not exceed the scribed line 30 with the width ranging from 30 to 130 μm. Therefore, the high-power solid-state laser used in the present invention can precisely cut the scribed lines 30 without injuring the surface 34 of the gallium nitride wafer.

In summary, the present invention proposes a high-power solid-state laser dicing apparatus for a gallium nitride wafer and a dicing method thereof, wherein the high-power solid-state laser with the parameters of a specific wavelength, frequency, energy density and beam diameter within the ranges proposed by the present invention has sufficient energy to enable its pulse to impact and ablate the scribed lines on the gallium nitride wafer so that the gallium nitride wafer can be rapidly diced. Accordingly, the present invention can save the manpower, cost and time of cutting a gallium nitride wafer and can precisely cut a gallium nitride wafer without injuring the wafer surface.

Those embodiments described above are only to clarify the present invention in order to enable the persons skilled in the art to understood, make and use the present invention but not intended to limit the scope of the present invention. Any equivalent modification and variation according to the spirit of the present invention disclosed herein is to be included within the scope of the claims stated below.

What is claimed is:

1. A high-power solid-state laser dicing apparatus for a gallium nitride wafer, comprising:
a working table, having a vacuum device to fix a gallium nitride wafer, which has multiple chips or dice with a scribed line drawn between every two said chips or dice;
a high-power solid-state laser, having a power ranging from 0.6 to 1.8 w, and used to cut said gallium nitride wafer into discrete said chips or dice;
a light-guide device, directing said high-power solid-state laser to one of said scribed lines on said gallium nitride wafer; and
a control device, coupled to and controlling said working table, said light-guide device and said high-power solid-state laser, and positioning said working table and said high-power solid-state laser to enable said high-power solid-state laser to be precisely aimed at one of said scribed lines on said gallium nitride wafer.

2. The high-power solid-state laser dicing apparatus for a gallium nitride wafer according to claim 1, further comprising at least one video device, which is used to observe whether said high-power solid-state laser has been precisely aimed at one of said scribed lines on said gallium nitride wafer.

3. The high-power solid-state laser dicing apparatus for a gallium nitride wafer according to claim 2, wherein said video device is installed above or below said working table.

4. The high-power solid-state laser dicing apparatus for a gallium nitride wafer according to claim 1, further comprising a focal-length-adjust element, which is disposed between said working table and said light-guide device and used to adjust the focal length by which said high-power solid-state laser is to be aimed at one of said scribed lines on said gallium nitride wafer.

5. The high-power solid-state laser dicing apparatus for a gallium nitride wafer according to claim 4, wherein said focal-length-adjust element is installed on an object lens.

6. The high-power solid-state laser dicing apparatus for a gallium nitride wafer according to claim 1, wherein said control device is a computer.

7. The high-power solid-state laser dicing apparatus for a gallium nitride wafer according to claim 1, wherein said the gallium nitride wafer having a thickness from 50 to 500 μm.

8. A high-power solid-state laser dicing method for a gallium nitride wafer, comprising the following steps:
providing a gallium nitride wafer, which has multiple chips or dice with a scribed line drawn between every two said chips or dice;
disposing said gallium nitride wafer on a working table;
positioning said working table and a high-power solid-state laser to enable said high-power solid-state laser to be precisely aimed at one of said scribed lines on said gallium nitride wafer in order to cut said gallium nitride wafer into multiple discrete said chips or dice;
inputting into a control device the length of one said scribed line to be cut and the spacing between said scribe line to be cut and another said scribed line to be cut next; and
sequentially cutting said scribed lines to separate said gallium nitride wafer into multiple discrete said chips or dice.

9. The high-power solid-state laser dicing method for a gallium nitride wafer according to claim 8, wherein said gallium nitride wafer is previously stuck onto a holding film and then said gallium nitride wafer together with said holding film is disposed on said working table.

10. The high-power solid-state laser dicing method for a gallium nitride wafer according to claim 8, wherein said working table uses a vacuum device to fix said gallium nitride wafer.

11. The high-power solid-state laser dicing method for a gallium nitride wafer according to claim 8, wherein said working table and said high-power solid-state laser are positioned by said control device.

12. The high-power solid-state laser dicing method for a gallium nitride wafer according to claim 8, wherein a focal-length-adjust element is used to adjust the focal length by which said high-power solid-state laser is to be aimed at one of said scribed lines on said gallium nitride wafer.

13. The high-power solid-state laser dicing method for a gallium nitride wafer according to claim 8, wherein during said step of “positioning said working table and a high-power solid-state laser”, at least one video device is used to observe whether said high-power solid-state laser has been precisely aimed at one of said scribed lines on said gallium nitride wafer.

14. The high-power solid-state laser dicing method for a gallium nitride wafer according to claim 8, wherein said high-power solid-state laser cuts said scribed lines into a depth larger than from one tenth to one second of the thickness of said gallium nitride wafer.

15. The high-power solid-state laser dicing method for a gallium nitride wafer according to claim 8, further comprising a step of “said high-power solid-state laser's automatically stopping operation” after said step of “sequentially cutting said scribed lines to separate said gallium nitride wafer into multiple discrete said chips or dice”.

16. The high-power solid-state laser dicing method for a gallium nitride wafer according to claim 15, further comprising a step of “shutting said vacuum device, and taking out said gallium nitride wafer, which has been cut well” after said step of “said high-power solid-state laser's automatically stopping operation”.

17. The high-power solid-state laser dicing method for a gallium nitride wafer according to claim 8, wherein said the gallium nitride wafer having a thickness from 50 to 500 μm.
